(19) United States
(12) Patent Application Publication
(10) Pub. No.: US 2019/0288096 A1
(43) Pub. Date: Sep. 19, 2019

(54) 4-LAYER DEVICES WITH IMPROVED REVERSE CURRENT ACTION CAPABILITY

(71) Applicant: Silicon Power Corporation, Clifton Park, NY (US)

(72) Inventor: Victor A. TEMPLE, Clifton Park, NY (US)

(21) Appl. No.: 16/277,534

(22) Filed: Feb. 15, 2019

Related U.S. Application Data
(60) Provisional application No. 62/773,877, filed on Nov. 30, 2018.
(60) Provisional application No. 62/631,197, filed on Feb. 15, 2018.

(51) Int. Cl. H01L 29/744; H01L 29/16; H01L 29/08

(52) U.S. Cl. CPC H01L 29/744; H01L 29/0839; H01L 29/0834; H01L 29/1608

(57) ABSTRACT

The present disclosure relates to four-layer latching devices having improved reverse current capabilities. The devices have a localized doping spike region in the upper base region, the lower base region, or both. The localized doping spike regions have a localized doping concentration that is greater than the doping concentration of the layer where the localized doping spike region is located. Within the base regions the localized spikes are located next to the corresponding upper emitter region, lower emitter region, or both.

### RELATED APPLICATIONS

This application claims the benefit of U.S. Provisional Application Nos. 62/773,877, filed Nov. 30, 2018, and 62/631,197, filed Feb. 15, 2018, the entire contents of which are incorporated herein by reference.

### FIELD OF THE INVENTION

The present disclosure relates to semiconductor devices and, more specifically, to four-layer latching devices.

### BACKGROUND OF THE INVENTION

Four-layer latching devices, including but not limited to thyristors, silicon-controlled rectifiers (SCRs), gate turn-off thyristors (GTOs), and super gate turn-off thyristors (SGTOs), have wide applications in controlling electric power.

SGTO's are pulse power devices capable of very high di/dt and action, with dense cell structures that employ 2-layer metal to bond with ceramic, 2-side metal ThinPak lids, which reduce stray inductance and resistance. ThinPak technology is a power semiconductor packaging technique developed by Silicon Power Corporation. The ThinPak packaging technique eliminates wire bonds, results in near 100% power module yields, reduces parasitics by an order of magnitude, and simplifies module manufacturing so that it can be automated as a simple pick and place operation. In some instances, the ThinPak technology generates preferred latching devices because of the relatively lower parasitic and size.

Four-layer latching devices can be turned on to allow large currents to pass through, and turned off by applying a reverse current or through a control gate signal. In a circuit that has inductance, typically a negative current pulse accompanies a positive current pulse. The degree of damping determines how large the reverse peak current is with respect to the forward peak current. Four-layer latching devices, unfortunately, tend to have very low reverse current capability relative to their forward current capability. As such, four-layer latching devices typically require additional circuit protection elements, which are impeded by inductance involved in transferring current into an alternate path, such as an antiparallel diode, and required time to become sufficiently modulated to be effective.

When a four-layer latching device is conducting in the forward direction, there are no blocking junctions. The upper and lower emitters are forward biased, and because the on-state carrier density at the forward blocking junction is relatively higher than the local doping, the device behaves as a forward biased diode whose resistance varies inversely with the modulation level. Although the resistance is relatively low, it still causes the device to heat up with a maximum near the center of the device. The heat is distributed between the emitter junctions, and thus, across most of the device thickness. The amount that the device heats up depends on a variety of parameters, including the volume of the material being heated, the specific heat capacity of the material, and the integral of current squared over time (I²t), which is also referred to as the action and represented in units of amperes of current squared times seconds (A² s). During the forward current pulse, the emitters remain relatively. Generally, the power loss in four-layer latching devices is based on resistance, and therefore, the temperature rise is approximately proportional to the forward biasing action. However, because of load and/or parasitic inductance, the circuit can induce a reverse current, in which case there is also reverse action.

In the reverse direction, at first one and then both emitter junctions will be pushed into avalanche by reverse current impressed by the circuit. Heat generated by the reverse biasing action is typically absorbed by depletion regions of the blocking junctions, which are much narrower than the volume of material absorbing heat in the forward direction. Thus, a device with a very large forward action may be forced to be derated as much as an order of magnitude to prevent a damaging temperature rise at either the upper or the lower emitter junction by the reverse action generated heat. If the circuit is over damped or critically damped, there will be no reverse current. In certain under-damped circuits, the ratio of negative to positive peak currents may be small enough that the emitter depletion region can absorb the heat without reaching its critical delta-T. For example, since forward current heating is roughly proportional to Iₚₑₐₖ², a device with an emitter depletion width 100× smaller than the emitter to emitter distance would have a similar temperature rise if its I_{Rpeak} were held to a 1/10 I_{Fpeak} undershoot, all other things being equal (e.g., similar pulse width and emitter avalanche voltage similar to positive current forward drop). In some situations, such as wider bandgap semiconductors, one or both emitter avalanche breakdown voltages can be about 1 or 2 orders of magnitude higher than the forward drop at peak current. In the reverse direction, conduction drop is generally swamped by reverse avalanche voltages of one or both emitter junctions, in which case losses are augmented in direct proportion to reverse current.

One option in increasing the allowable reverse action is to minimize the stray inductance, which drives the damping factor in the right direction and also lowers the voltage requirement for their energy source. A high turn-on speed anti-parallel high voltage diode with a sufficient action rating, and a voltage rating at least equal to the switching device may be inserted. Series lower voltage diodes are faster, but each requires the same action and cooling and increase cost and inductance. A perfect diode with zero device/diode coupling inductance L_{D} shunts all the reverse current. However, real diodes take time to reach a modulation level sufficient to lower their impedance below that of the already carrier flooded (largely by avalanche generation) main device. The lower the di/dt at zero current crossing the less perfect the diode can be and the more realistic the diode-main device current loop inductance L_{D}. An example is provided later with 6.5 kilovolt (kV) silicon devices and 1 nanohenry (nH) L_{D} for a 3.85 microsecond (μs) half-width pulse in which only ⅙ of the reverse action has managed to shift to the diode.

As discussed above, the heat generated by the reverse action is dependent on a number of factors, for example the peak reverse current, the breakdown voltage of the junctions, and the width of the depletion region. FIG. 1 illustrates a doping profile 10 along a vertical cut line in a latching device's 4-layer latching region. The latching device is a silicon carbide (SiC) p-type SGTO. In FIG. 1, the doping profile 10 comprises an anode metal region 12, a cathode metal region 14. To latch the device, gate regions are distributed by either etching down to the upper base region 18 or by selectively preventing the formation of the upper emitter region 16. Then low ohmic contact metal is applied to these gate regions often combined by a local heavy and shallow implant of any suitable element known in the art. The doping profile 10 of the latching device further comprises an upper emitter region 16, an upper base region 18, a lower base region 20, a lower base buffer region 22, a lower emitter region 24, an upper emitter junction 26, and a lower emitter junction 28. The doping profile 10 of FIG. 1 has an x-axis in microns, which represents the width (or thickness) of the latching device. The regions each have a respective doping concentration. For example, the upper emitter region 16 has a first doping concentration, the upper base region 18 has a second doping concentration, the lower base region 20 has a third doping concentration, the lower emitter region 24 has a fourth doping concentration, and the lower base buffer region 22 has a fifth doping concentration.

FIG. 2 illustrates voltage, current, and temperature responses of the prior art device that has a doping profile 10 shown in FIG. 1. Initial temperature is around 300 Kelvin (K), and SiC die active area is approximately 1 centimeter squared (cm²), as are all of the devices simulated in this patent application. The top chart illustrates an upper junction going into avalanche mode at 84 volts. This upper junction is referred to hereon as the top emitter junction and so-called because it is the face of the wafer that is patterned for purposes of breakdown voltage and gating. About 0.5 μs later, the lower junction, hereon denoted as the lower emitter junction, goes into avalanche mode, contributing another 546 volts. As can be seen in the temperature response chart, in the reverse direction, a very large temperature spike occurs at the lower junction on the right side of the chart, and a smaller temperature spike occurs at the upper junction on the left side of the chart. FIG. 2 also provides the change in temperature per μs between a couple of time points for the upper and lower junctions. In this example, the change is approximately 90 K/μs and 673 K/μs, respectively.

The top graph in FIG. 2 is instructive. After a 3.8 μs half-width pulse 1476 volts (V), 55 micro Fared (μF) capacitor discharge into a 15 mΩ, 60 nH load plus strays, with a 3e3 A²s action, the temperature rise has been only 2K, which dT at zero crossing is tabulated in the inset table in the lower graph. When the current reverses the device voltage is upper emitter junction, avalanche clamped at −84 V and the dT gets to 200 K. After 0.5 μs the lower emitter adds its avalanche clamped voltage, whose losses are large enough to quickly damp the back half of the negative current oscillation. This is how bad the situation is. The forward 32.4 (kilo amp) kA pulse with 3e4A²s action raises peak device dT to 2K for an extrapolated pulse life of (dT_{crit}/2)⁹ pulses while 45e4A²s action reverse pulse raise the peak dT to about 950 K. FIG. 2 also assumes T_{crit,Si} is 400 K and twice that for dT_{crit,SiC}. Regardless, the device shown in FIG. 2 has a relatively high forward capability and virtually zero reverse capability, even though reverse peak current was only −5.5 kA. Note that the zero crossing di/dt is quite small, and given that SiC diodes turn on very quickly, an antiparallel diode might provide adequate shunting, provided the stray impedance in its path is small enough. For very wide reverse current pulse the very large temperature spike of FIG. 2 is moderated by heat flow away from the peak into cooler adjacent semiconductor, and into the anode and/or cathode metal which are depicted in FIG. 1

FIGS. 3-5 illustrate voltage, current, and temperature responses of a prior art silicon (Si) n-type latching device. The Si latching device of the prior art has lower avalanche breakdown voltages at its junctions than in the SiC prior art device, and the disparity between forward action and reverse action capabilities is smaller than the SiC prior art device because the emitted depletion regions at avalanche are 5 to 10 time wider. Nevertheless, the Si n-type latching device still experiences significant temperature rises at its junctions when conducting in the reverse direction and are the limiting factor is narrow pulse under damped discharge circuits.

For purpose of comparison the discharge circuit (55 μF, 60 nH, 60 mOhm) for the SiC case shown in FIG. 2 has been used for Si cases depicted in FIGS. 3 and 4, but charged to 1725 V with 37.2 kA peak current rather than the 1478 V and 32.4 kA of FIG. 2. Pulse widths are identical. Some of the good things about SiC are evident. In FIG. 3, 8 μs half width pulse of roughly 6 μs base width the FIG. 2 SiC device is fully modulated before the current reaches Ipk/10, while the silicon devices of FIGS. 3 and 4 may not quite manage to be fully on, in which case its Vf would be likely higher than that of the SiC device despite its lower diode drop. This is evident in the forward current pulse temperature rise, 2 K for the SiC case, and 28.4 K for the silicon case.

Since FIG. 3 has added an antiparallel silicon diode to the circuit, for the purposes of reverse current comparison, FIG. 4 may be more accurate for the silicon comparison. FIG. 4 depicts that the lower avalanche voltages in silicon's reverse biased emitter junctions have a decisive impact. The top left graph shows dT*10, I_{A}/20 and VA, which is VL while the other 3 graphs plot the lattice temperature in degree K across the device and into 4 mil copper electrodes, which represent as much of the final packaged device as we need for accuracy given the shortness of the heat pulse. The entire device plus the immediate apart of the electrodes are shown in the upper right, with zooms to the upper and lower emitters for the bottom two graphs. First notice that there is low enough reverse voltage and energy loss at avalanche that there is a full reverse current pulse with a second current zero. It has a peak of −16.7 kA at −61.1 V and dT of 184 K on the way to a maximum dT 1.5 μs later of 208 K. In all three temperature plots the bottom curve in red is taken at peak forward current and the immediate one above it at first zero crossing. Notice, too, that the hottest part of the device is in the low doped portion of the wide base. Then, with reverse current, both the upper and lower emitters heat up rapidly, then begin to cool even before the second current zero due to heat spread overcoming power dissipation. This is similar to the lower graph of FIG. 2. In both silicon and SiC cases the highest dT is at the lower emitter and would be expected because of the design requirement for a high gain upper transistor whose base doubles as the base of the upper emitter. Note that the maximum dT/dt is shown in the various temperature graphs and occurs at the upper emitter, 80K/μs for SiC and 28.5K/μs for silicon. And at the lower emitter it is 673K/μs for SiC and 65.8K/μs for silicon.

In FIG. 3 the same silicon wafer has been processed as a state of the art diode and optimized for minimum forward drop and turn-on time and has an identical lower emitter, buffer and base as the thyristor, but with a p+ upper emitter replacing the thyristor upper emitter/base diode. It has the same 4-mil copper electrodes and is presumed to have a negligible stray impedance between it and the pulse silicon device. Note that the voltage scale has changed to more clearly see that the silicon device is never fully on during the forward pulse and is tagged at 37.3 kA, 28.6 V and at 321.2 K, initial temperature being 300 K for all simulations in this application. We do not plot the diode current, but rather the device current and the total of the device and diode. It takes about 3.5 μs before the diode current equals device current and another ½ μs before almost all of the current is in the diode. Shown in the figure are the respective actions, 500A2s for the device and 104A2s for the diode. In other words for this 3.8 μs half-width pulse adding an antiparallel silicon diode provides little improvement, even if there is no stray inductance to slow the current transfer.

Generally, large temperature spikes at the junctions can damage the device and reduce the number of cycles of operation before the device fails. Reducing the temperature spikes increases the reliability and the number of cycles before the device fails. There is therefore a need for a four-layer latching device that can minimize temperature spikes associated with the reverse action.

### SUMMARY OF THE INVENTION

In accordance with an aspect of the present disclosure, there is provided a four-layer semiconductor latching device that includes at least an upper emitter region having a first doping concentration; an upper base region having a second doping concentration; a lower base region having a third doping concentration; a lower emitter region having a fourth doping concentration; an upper emitter junction formed at an interface between the upper emitter region and the upper base region; and a lower emitter junction formed at an interface between the lower base region and the lower emitter region; wherein the upper base region comprises an upper localized doping spike region at the upper emitter junction, wherein the upper localized doping spike region has an upper localized doping concentration greater than the lower doping concentration, and wherein the lower base region further comprises a buffer region at the lower emitter junction, the buffer region having a fifth doping concentration.

In accordance with another aspect of the present disclosure, there is provided a four-layer semiconductor latching device that includes at least an upper emitter region having a first doping level; an upper base region having a second doping level; a lower base region having a third doping level; a lower emitter region having a fourth doping level; an upper emitter junction formed at an interface between the upper emitter region and the upper base region; and a lower emitter junction formed at an interface between the lower base region and the lower emitter region; wherein the lower base region further comprises a buffer region at the lower emitter junction, the buffer region having a fifth doping concentration, and further wherein an upper localized doping spike region is in the buffer region and has an upper localized doping concentration is greater than the fifth doping concentration.

In accordance with another aspect of the present disclosure, there is provided a semiconductor latching device that includes at least an upper emitter junction formed at an interface between an upper emitter region having a first doping concentration and an upper base region having a second doping concentration; and a lower emitter junction formed at an interface between a lower base region having a third doping concentration and the lower emitter region having a fourth doping concentration; wherein the upper base region comprises an upper localized doping spike region at the upper emitter junction, wherein the upper localized doping spike region has an upper localized doping concentration greater than the second doping concentration, and wherein the lower base region does not include a lower localized doping spike region at the upper emitter junction and a buffer region at the lower emitter junction.

In accordance with another aspect of the present disclosure, there is provided a semiconductor latching device that includes at least an upper emitter junction formed at an interface between an upper emitter region having a first doping concentration and an upper base region having a second doping concentration; and a lower emitter junction formed at an interface between a lower base region having a third doping concentration and the lower emitter region having a fourth doping concentration; wherein the upper base region comprises an upper localized doping spike region at the upper emitter junction, wherein the upper localized doping spike region has an upper localized doping concentration greater than the second doping concentration, wherein the lower base region does not include a lower localized doping spike region at the upper emitter junction, and wherein the lower base region comprises a buffer region having a fifth doping concentration at the lower emitter junction.

### BRIEF DESCRIPTION OF THE DRAWINGS

For the purpose of illustration, there are shown in the drawings certain embodiments of the present disclosure. In the drawings, like numerals indicate like elements throughout. It should be understood that the invention is not limited to the precise arrangements, dimensions, and instruments shown. In the drawings:

FIG. 1 illustrates a doping profile of a silicon carbide p-type SGTO according to a typical epitaxy-based process.

FIG. 2 illustrates a voltage, current, and temperature response of the silicon carbide SGTO illustrated in FIG. 1 during a several μs half-width pulse discharge of a charged capacitor into an R-L load.

FIG. 3 illustrates a voltage, current, and temperature response of a silicon n-type SGTO according a typical implant/diffusion based silicon process with a similarly designed antiparallel diode during a several μs half-width pulse discharge of a charged capacitor into an R-L load.

FIG. 4 illustrates a voltage, current, and temperature response of a silicon n-type SGTO during a several μs half-width pulse discharge of a charged capacitor into an R-L load.

FIG. 5 illustrates a voltage, current, and temperature response of a silicon n-type SGTO, during a sub-μs half-width pulse discharge of a charged capacitor into an R-L load.

FIG. 6A illustrates an asymmetric p-type SGTO in accordance with an exemplary embodiment of the present disclosure.

FIG. 6B illustrates an asymmetric n-type SGTO in accordance with an exemplary embodiment of the present disclosure.

FIG. 7 illustrates a doping profile of the asymmetric p-type SGTO of FIG. 6A, in accordance with an exemplary embodiment of the present disclosure that used epitaxy to realize the desired doping profile.

FIG. 8 illustrates voltage, current, and temperature responses of the asymmetric p-type SGTO of FIG. 6A, in accordance with an exemplary embodiment of the present disclosure as applied to the cathode emitter-base junction during a several μs half-width pulse discharge of a charged capacitor into an R-L load.

FIG. 9 illustrates voltage, current, and temperature responses of the asymmetric p-type SGTO of FIG. 6A, in accordance with an exemplary embodiment of the present disclosure as applied to both upper and lower emitter-base junctions during a several μs half-width pulse discharge of a charged capacitor into an R-L load.

FIG. 10 illustrates voltage, current, and temperature responses of the asymmetric p-type SGTO of FIG. 6A, in accordance with an exemplary embodiment of the present disclosure applied to both upper and lower emitter-base junctions during a sub-μs half-width pulse discharge of a charged capacitor into an R-L load.

FIG. 11 compares of a doping profile of a silicon asymmetric n-type SGTO of FIG. 6B, in accordance with an exemplary embodiment of the present disclosure, with a doping profile of an asymmetric n-type SGTO according to the prior art.

FIG. 12 illustrates voltage, current, and temperature responses of the asymmetric n-type SGTO of FIG. 6B, in accordance with an exemplary embodiment of the present disclosure applied to both upper and lower emitter-base junctions to affect the sub-μs half-width pulse discharge of a charged capacitor into an R-L load.

FIG. 13 illustrates a circuit having a four-layer device and antiparallel diodes, according to an exemplary embodiment of the present disclosure.

FIG. 14A illustrates a partially symmetric p-type SGTO in accordance with an exemplary embodiment of the present disclosure.

FIG. 14B illustrates a partially symmetric p-type SGTO that includes a doping blocking layer in accordance with an exemplary embodiment of the present disclosure.

FIG. 15 illustrates Table 1 that presents a variety of parameter values for various embodiments of the present disclosure.

FIG. 16 illustrates Tables 2A and 2B that presents a variety of parameter values for various embodiments of the present disclosure.

### DETAILED DESCRIPTION OF THE INVENTION

For purposes of this disclosure, an upper side emitter of a four-layer latching device refers to the masked side or the side nearest the forward block junction. Conversely, the lower side emitter of the four-layer latching device refers to the side farthest away of the forward block junction. For example, in a p-type four-layer latching device, the upper side emitter is the anode and the lower side emitter is the cathode. In another example, in a n-type four-layer latching device, the upper side emitter is the cathode and the lower side emitter is the anode. The upper side emitter can also be referenced as and interchangeable throughout this disclosure with the terms “upper emitter,” “emitter 1,” and “first emitter.” The lower side emitter can also be referenced as and interchangeable throughout this disclosure with the terms “lower emitter,” “emitter 2,” and “second emitter.”

This disclosure includes various example embodiments that increase the allowable reverse action for a four-layer latching device by modifying the emitter depletion regions. In one example, the four-layer latching device includes an emitter depletion region on the base side of the junction modified to be narrower with a locally high doping spike. By doing so, the four-layer latching device has a relatively lower emitter-base break down voltage. For example, a SiC device with the modified emitter depletion regions could have a reduction in avalanche break down voltage of about a factor of 10 for an estimated increase in reverse action rating of about a factor of 3.

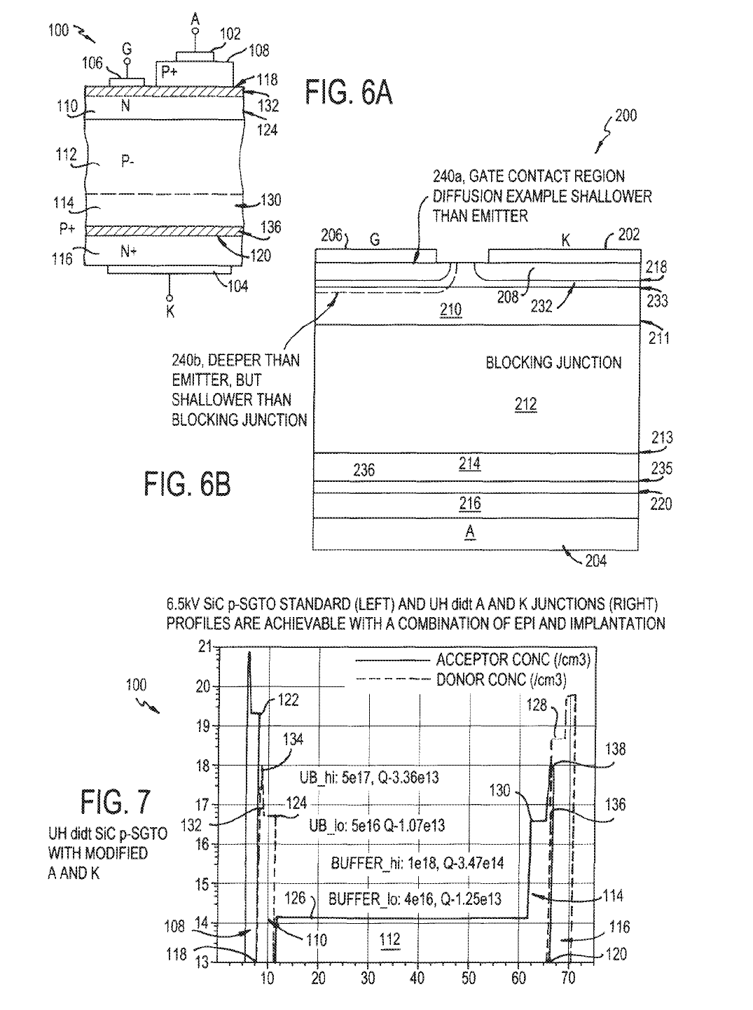

FIG. 6A illustrates an asymmetric p-type SGTO in accordance with an exemplary embodiment of the present disclosure. In FIG. 6A, the four-layer latching device generally designated as 100 represents an epi-based latching device. In particular, the latching device 100 is an asymmetric p-type SGTO and comprises an anode metal 102, a cathode metal 104, and a gate metal 106. The latching device 100 further comprises an upper emitter region 108 that contacts the anode metal 102, an upper base region 110, a lower base region 112, a buffer region 114, a lower emitter region 116 that contacts the cathode metal 104, an upper emitter junction 118, a lower emitter junction 120, and a gate contact region that may be shallower than the upper emitter region 108, or a gate contact region that may be deeper than the upper emitter region 108. In FIG. 6A, the upper emitter region 108 contacts and/or is laid above of at least a portion of the upper base region 110, and the lower base region 112 contacts and/or is laid above at least a portion of the lower emitter region 110. The buffer region 114 is part of the lower base region 112, which in FIG. 6A is a p-type material.

The upper emitter junction 118 may be formed at an interface between the upper emitter region 108 and the upper base region 110. The lower emitter junction 120 may be formed at an interface between the buffer region 114 and the lower emitter region 116. As shown in FIG. 6A, the upper base region 110 includes an upper localized doping spike region 132 at the upper emitter junction 118, and the lower localized doping spike region 136 is located in the buffer region 114 at the lower emitter junction 120. In the case of the SGTO power electrodes, solder and copper are typically bonded over their entire areas of the device metal to provide the closest possible sink for heat generated at the junctions.

FIG. 7 illustrates a doping profile of the latching device 100 of FIG. 6A, according to an exemplary embodiment. Specifically, the doping profiles shown in FIG. 7 correspond to an epitaxy-based p-type SiC SGTO. The respective regions of the latching device 100 each have a respective doping concentration. For example, the upper emitter region 108 has a first doping concentration 122, the upper base region 110 has a second doping concentration 124, the base region 112 has a third doping concentration 126, the second emitter region 116 has a fourth doping concentration 128, and the buffer region 114 has a fifth doping concentration 130.

The breakdown voltages of the upper emitter junction 118 and the lower emitter junction 120 impact the reverse action capability of the latching device 100. In the reverse direction, the power absorbed by the latching device 100 depends on the reverse current and the avalanche breakdown voltage of the junctions (P=VI). The power per unit volume can be determined by multiplying the reverse current by the breakdown voltage, and dividing by the volume of the junction interfaces. Junction interfaces are typically very thin. For example, the junction interfaces may be approximately sub-micron thick on the emitter side of the interface and several microns on the base side. A person of ordinary skill in the art would understand that the actual thickness of the junction interfaces may vary, but in any event the thickness is significantly smaller than the layers of the four-layer latching device 100.

Heat generated by the reverse current is primarily absorbed in the very thin junction interfaces and is largely proportional to the power resulting from the reverse current. The amount of heat may be reduced by decreasing the amount of power absorbed in the reverse direction. Since power is dependent on the breakdown voltages of the junctions, the power (and therefore the net heat) may be reduced by lowering the breakdown voltages of the junctions. Embodiments in the present disclosure successfully reduce the breakdown voltages of one or both of the junctions that block in reverse current operation, with negligible impact on the forward action capability of the latching device 100, by introducing localized doping spike regions near the junction regions.

In an exemplary embodiment, the upper base region 110 includes an upper localized doping spike region 132 at the upper emitter junction 118. The upper localized doping spike region 132 has an upper localized doping concentration 134 greater than the second doping concentration 124 of the upper base region 110. The width of the upper localized doping spike region 132 is narrower than the width of the upper base region 110. For example, the width of the upper localized doping spike region 132 may be less than half of the width of the upper base region 110. The exact width may be adjusted depending on the desired characteristics of the device 100.

In general, the present disclosures provide embodiments that reduce the avalanche voltage of the emitter-base junctions by having localized doping concentrations as high as possible with enough width such that the integrated net doping approaches or exceeds E_{crit}*ε/e. For example, in SiC, a localized doping concentration may be approximately 1e18/cm³ for 0.3 μm for abrupt epitaxy layers. In Si, a localized doping concentration may be 1e17/cm³ for 0.3 um for abrupt epitaxy layers. It is understood by those skilled in the art that the localized doping concentrations may be adjusted as necessary depending on the application and characteristics of the device. Wider localized doping spike regions are acceptable provided the transistor gain of the associated emitter-base remains high. It is important that the junction be abrupt to reduce the voltage across a low-doped region in the vicinity of the junction. The considerations regarding minimizing breakdown voltage and maintaining high gain are generally known to those skilled in the art. In general, a localized doping spike region will be only a portion of the net base width, adding to the normal, deeper base profile. Generally, the higher the localized doping spike region is doped, the narrower the width of the localized doping spike region. This results in less recombination as carriers pass through the base region, and therefore, a higher transistor gain. This trade-off is a second order effect because the spike region is relatively narrow, and the added net doping is too small to cause a significant increase on overall emitter to emitter recombination at high forward currents.

The upper localized doping concentration 134 is greater than the second doping concentration 124 of the upper base region 110. In an exemplary embodiment, the upper localized doping concentration 134 is at least 50% larger than the second doping concentration 124 of the upper base region 110. In other embodiments, the upper localized doping concentration 134 is at least twice as large, at least three times as large, or at least five times as large as the second doping concentration 124, aiming at avalanche breakdown reduction to ⅔, ½, ⅓ and ⅕ or lower as compared to the prior art device. Recall that reducing the avalanche breakdown reduces the power (and therefore the net heat) of the latching device 100 when compared to the prior art device.

In another exemplary embodiment, the lower localized doping spike region 136 may be located in the buffer region 114 at the lower emitter junction 120, on the cathode side of the latching device 100. The lower localized doping spike region 136 has a localized doping concentration 138 greater than the fifth doping concentration 130 of the buffer region 114. The width of the lower localized doping spike region 136 is narrower than the width of the buffer region 114. In fact, the width may be as wide as to have an integrated charge large enough to lower the field at the lower emitter junction 120 in avalanche to a relatively small fraction. For example, the width of the lower localized doping spike region 136 may be less than half of the width of the buffer region 114. The exact width of the lower localized doping spike region 136 may be adjusted depending on the desired characteristics of the device 100.

The lower localized doping concentration 138 is greater than the fifth doping concentration 130 of the buffer region 114. In an exemplary embodiment, the lower localized doping concentration 138 is at least 50% larger than the fifth doping concentration 130 of the buffer region 114. In other embodiments, the lower localized doping concentration 138 is at least twice as large, at least three times as large, or at least five times as large as the fifth doping concentration 130, aiming at avalanche breakdown reduction to ⅔, ½, ⅓ and ⅕ or lower as compared to the prior art device 10. In one or more embodiments, the latching device 100 can include a localized doping concentration at either the upper base region 110, the lower base region 112, or both.

FIG. 6B illustrates another embodiment of a four-layer latching device. FIG. 6B depicts a four-layer latching device, generally designated as 200, in accordance with an exemplary embodiment of the present disclosure. The latching device 200 is an asymmetric Si n-type SGTO and comprises a cathode metal 202, an anode metal 204, and a gate metal 206. The latching device further comprises an upper emitter region 208, an upper base region 210, a lower base region 212, a buffer region 214, a lower emitter region 216, an upper emitter junction 218, and a lower emitter junction 220. The respective regions of latching device 200 each have a respective doping concentration. For example, the upper emitter region 208 has a first doping concentration, the upper base region 210 has a second doping concentration, the lower base region 212 has a third doping concentration, the lower emitter region 216 has a fourth doping concentration, and the buffer region 214 has a fifth doping concentration 213.

In an exemplary embodiment, the upper base region 210 includes an upper localized doping spike region 232 at the upper emitter junction 218. The upper localized doping spike region 232 has a first localized doping concentration 233 greater than the second doping concentration 211 of the upper base region 210. The width of the upper localized doping spike region 232 is narrower than the width of the upper base region 210. For example, the width of the upper localized doping spike region 232 may be less than half of the width of the upper base region 210. The exact width may be adjusted depending on the desired characteristics of the latching device 200.

The upper localized doping concentration 233 is greater than the second doping concentration of the upper base region 210. In an exemplary embodiment, the upper localized doping concentration 233 is at least 50% larger than the second doping concentration 211 of the upper base region 210. In other embodiments, the upper localized doping concentration 233 is at least twice as large, at least three times as large, or at least five times as large as the second doping concentration 211.

In another exemplary embodiment, rather than having the upper localized doping spike region 232 located in the upper base region 210, a localized doping spike region 236 may be located in the buffer region 214 at the lower emitter junction 220. Recall that the lower emitter junction 220 may correspond to the anode 204 side of the latching device 200. With reference to FIG. 6B, the localized doping spike region corresponds to the lower localized doping spike region 236. The lower localized doping spike region 236 has a localized doping concentration 235 greater than the fifth doping concentration 213 of the buffer region 214. The width of the lower localized doping spike region 236 is narrower than the width of the buffer region 214. For example, the width of the lower localized doping spike region 236 may be less than half of the width of the buffer region 214. The exact width of the lower localized doping spike region 236 may be adjusted depending on the desired characteristics of the latching device 200.

The lower localized doping concentration 236 is greater than the fifth doping concentration 213 of the buffer region 214. In an exemplary embodiment, the lower localized doping concentration 236 is at least 50% larger than the fifth doping concentration 213 of the buffer region 214. In other embodiments, the lower localized doping concentration 236 is at least twice as large, at least three times as large, or at least five times as large as the fifth doping concentration 213.

In another exemplary embodiment, instead of having one emitter junction with a localized doping spike, each emitter junction in the latch device 200 may have a localized doping spike. The upper base region 210 includes an upper localized doping spike region 232 at the upper emitter junction 218. The upper localized doping spike region 232 has an upper localized doping concentration 233 greater than the second doping concentration 211 of the upper base region 210. The width of the upper localized doping spike region 232 is narrower than the width of the upper base region 210. For example, the width of the upper localized doping spike region 232 may be less than half of the width of the upper base region 210. A lower localized doping spike region 236 is located in the buffer region 214 and has a lower localized doping concentration 235 greater than the fifth doping concentration 213. The width of the lower localized doping spike region 236 is narrower than the width of the buffer region 214. For example, the width of the lower localized doping spike region 236 may be less than half of the width of the buffer region 214. The widths of the upper localized doping spike region 232 and the lower localized doping spike region 236 may be adjusted depending on the desired characteristics of the latching device 200.

The upper localized doping concentration 233 is greater than the second doping concentration 211 of the upper base region 210. In an exemplary embodiment, the upper localized doping concentration 233 is at least 50% larger than the second doping concentration of the upper base region 210. In other embodiments, the upper localized doping concentration 233 is at least twice as large, at least three times as large, or at least five times as large as the second doping concentration 211.

The lower localized doping concentration 235 is greater than the fifth doping concentration 213 of the buffer region 214. In an exemplary embodiment, the lower localized doping concentration 235 is at least 50% larger than the fifth doping concentration 213 of the buffer region 214. In other embodiments, the lower localized doping concentration 235 is at least twice as large, at least three times as large, or at least five times as large as the fifth doping concentration 213. Having the upper localized doping concentration 233 and lower localized doping concentration to be larger than the upper base region 210 and buffer region 214, respectively, reduces the reverse breakdown voltages at the both the upper and lower ends of the latch device 200.

In FIG. 6A, the net doping profiles for latching device 100 can be achieved best by epitaxy (commonly used for SiC devices), and in FIG. 6B, the net doping profiles for latching device 200 can be achieved by implantation and diffusion (commonly used in silicon devices). Other embodiments of latching device 100 may have net doping profiles created from a combination of epitaxy, implantation, and diffusion or other means known in the art. As an example, to lower contact resistance for the gate metal 106, creating the latching device 100 may involve using an implant and minimum temperature activation if the surface doping of 132 are relatively low or if an etch defining the upper emitter region 108 are relatively deeper. Box implants are examples of using implantation and diffusion to lower contact resistance for the gate metal 106. Additionally or alternatively, a manufacturing process could generate the lower emitter junction 120 and buffer region 114 by epitaxy onto a wafer of doping, where the thickness of the epitaxy is based on a desired voltage rating. The wafer could be flipped over to be finished with conventional implant and diffusion processes. Utilizing low temperature wafer bonding would also provide a large degree of freedom as the upper side and lower side could be separately optimized, with part of the necessary thickness for the desired voltage rating coming from the upper emitter wafer and part from the lower emitter wafer.

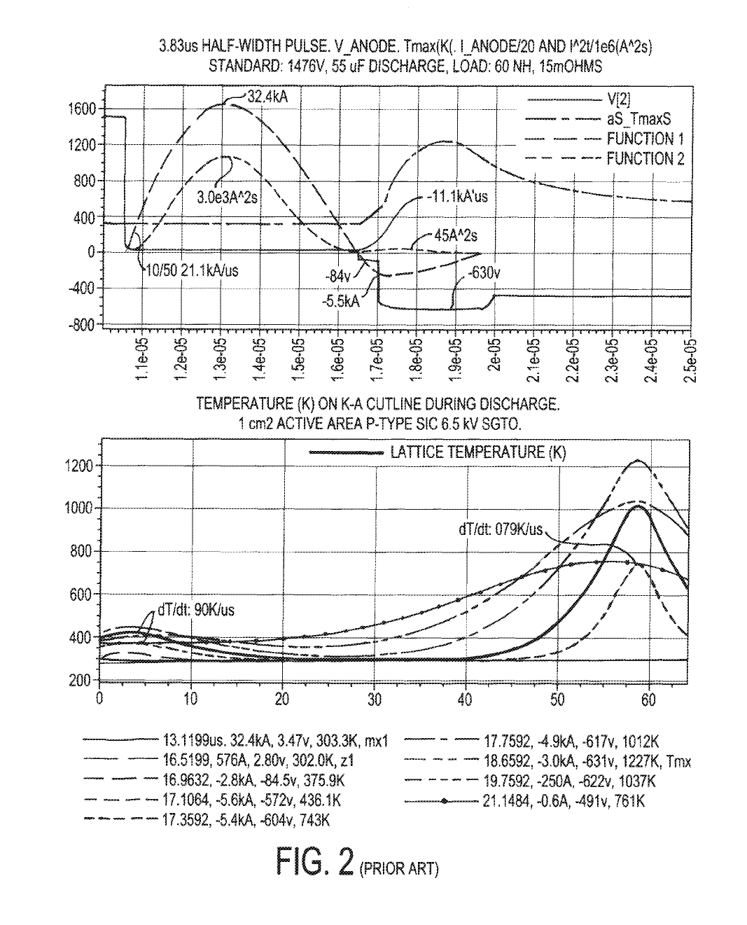

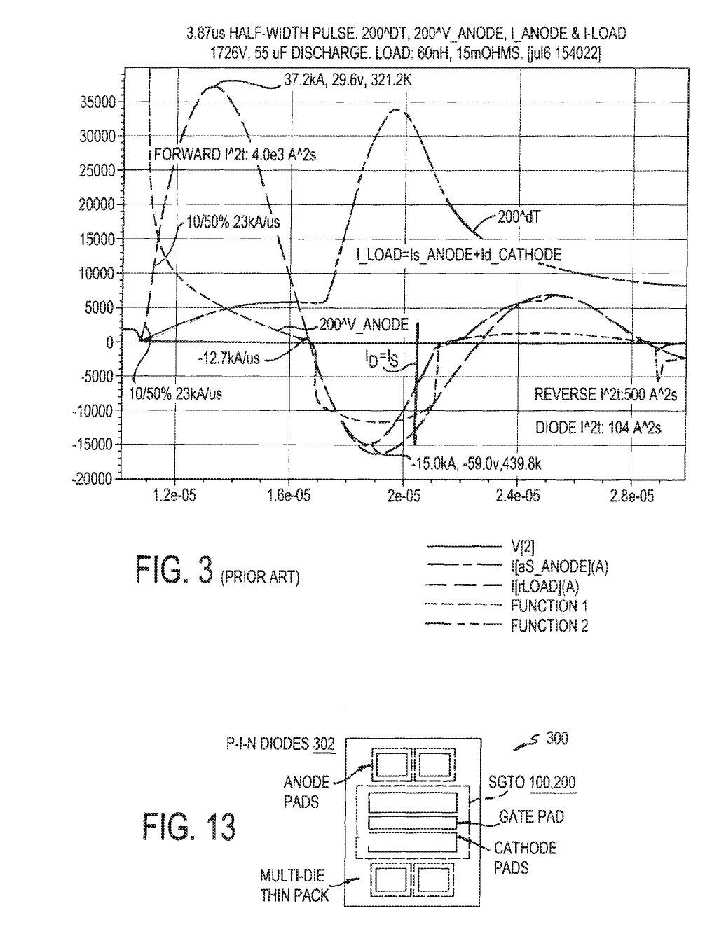

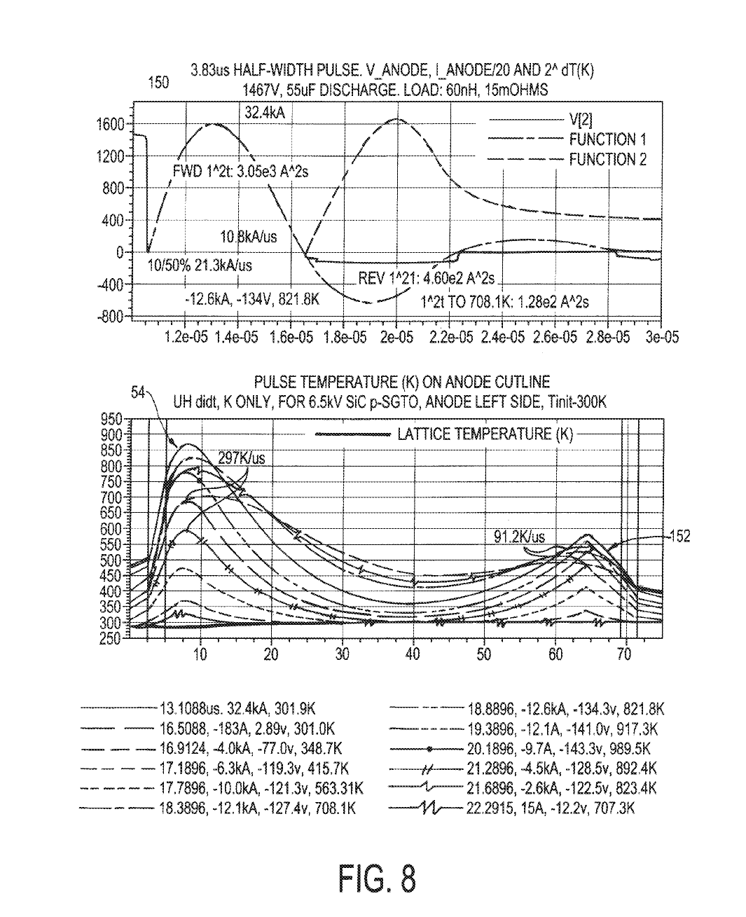

Turning to FIG. 8, voltage and current (top panel) and resulting temperature snapshots at key times are illustrated for an exemplary SiC p-type SGTO in which only the lower localized doping spike region shown has been inserted to produce precisely the doping profile of FIG. 7 absent the upper localized doping spike region. The lower localized doping spike region is located near a lower emitter junction (in this p-type example, the cathode emitter) on the right side of the chart. In all such charts the left side is the upper portion of the device containing emitter 1. The result is a temperature profile, unchanged from that of FIG. 2 on the emitter 1 side of the device, but dramatically improved for emitter 2 in the lower portion of the device. Key results of the device pulse discharge are labeled in the upper chart. In the lower chart internal temperatures are plotted as a function of time and an inset table provided to indicate internal current, voltage and temperatures at key times such as maximas, minimas and zero current crossings. Summary tables are supplied later that include most of the data shown in the inset figures.

FIG. 8 shows a peak forward current 150 that is approximately the same as the prior art devices, which indicates that the localized doping spike region had minimal impact on the forward action capability of the device. However, under similar testing conditions as illustrated in the prior art response in FIG. 2, the exemplary device tested in FIG. 8 has a significantly reduced temperature spike 152 on the lower side of the device. The prior art device experienced a peak temperature amplitude of over 1200K and a temperature rate of change, dT/dt, of approximately 673K per μs, whereas the device of the present disclosure experienced a peak temperature amplitude of under 600K and a temperature change of approximately 91.2K per μs at the emitter 2 junction on the lower side of the device.

FIG. 8 also shows that a temperature spike 154 at the junction without a localized doping spike region on the upper side of the device, has become the device limiting factor, which is why we advise reducing avalanche BV of the upper emitter junction as well.

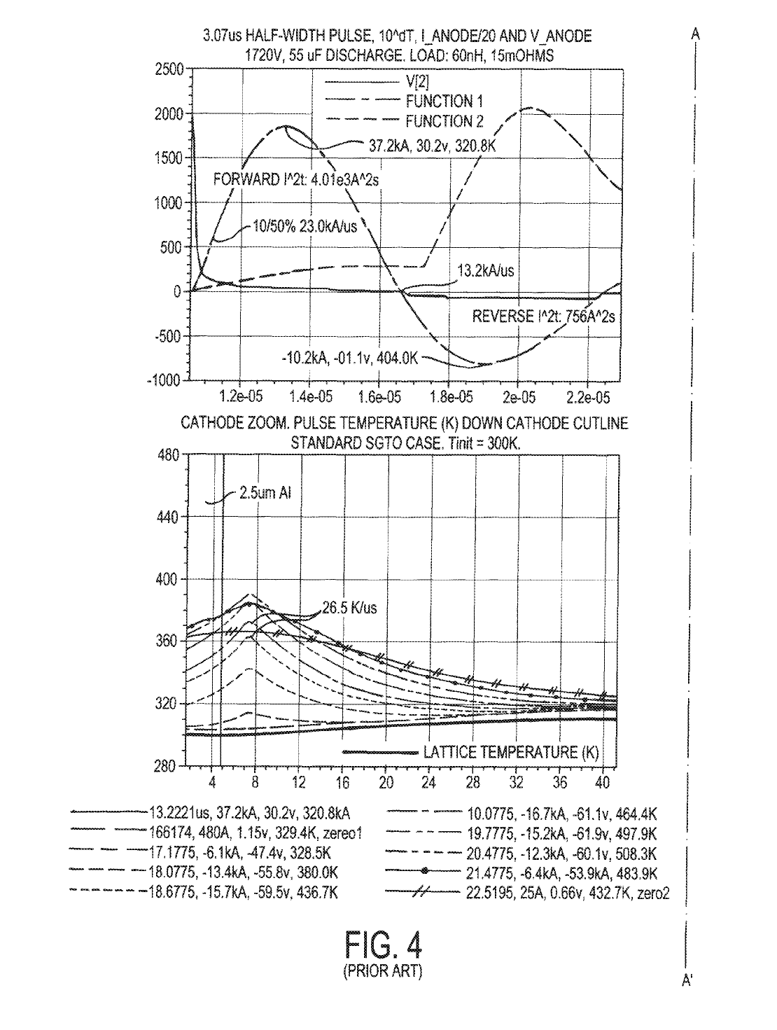

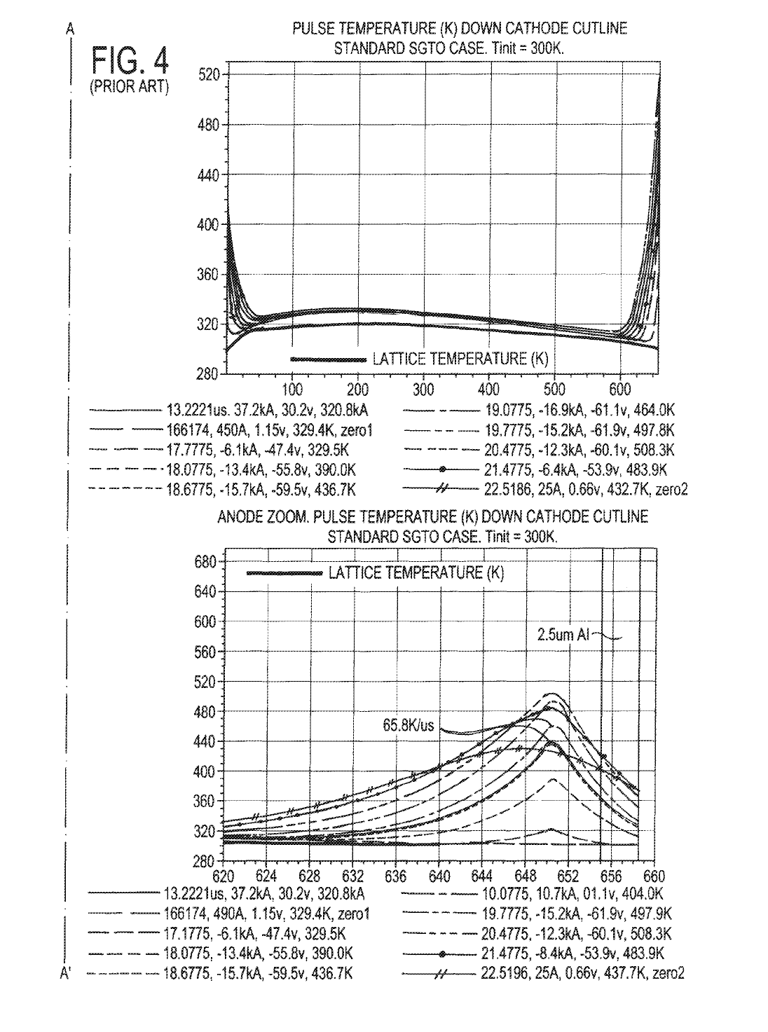

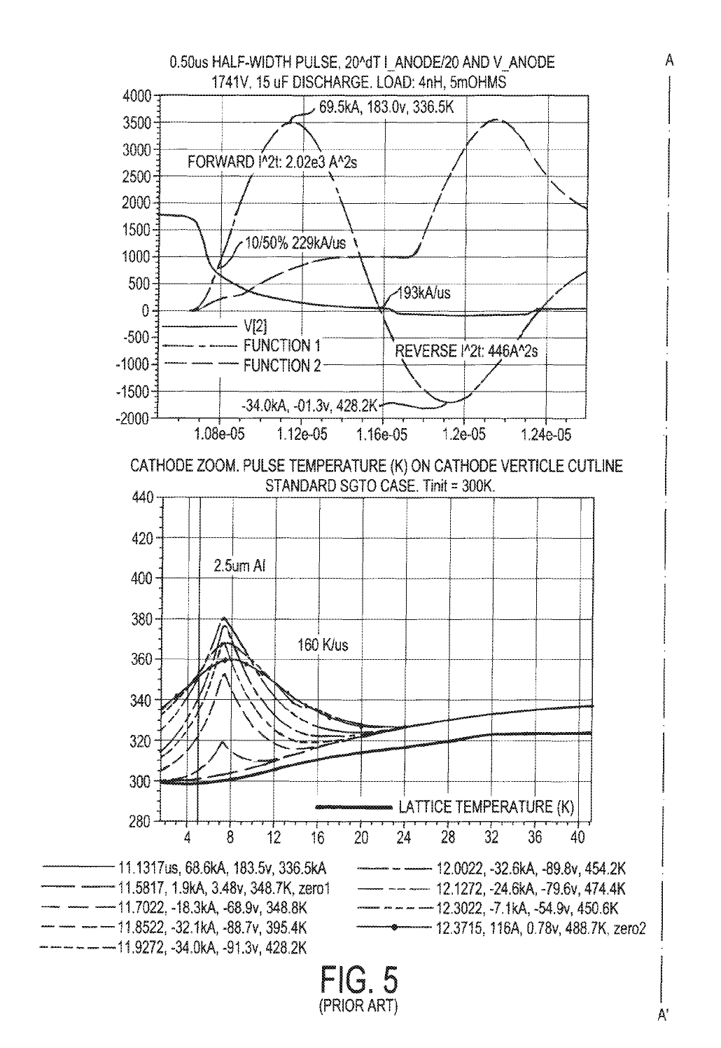

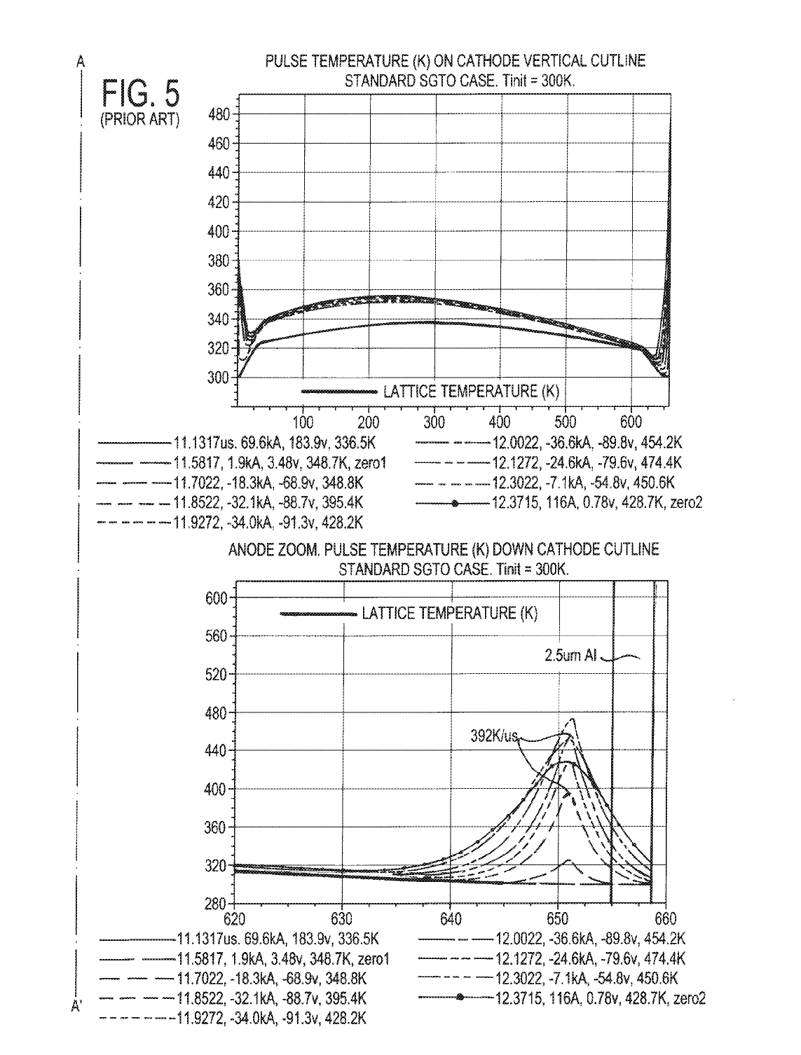

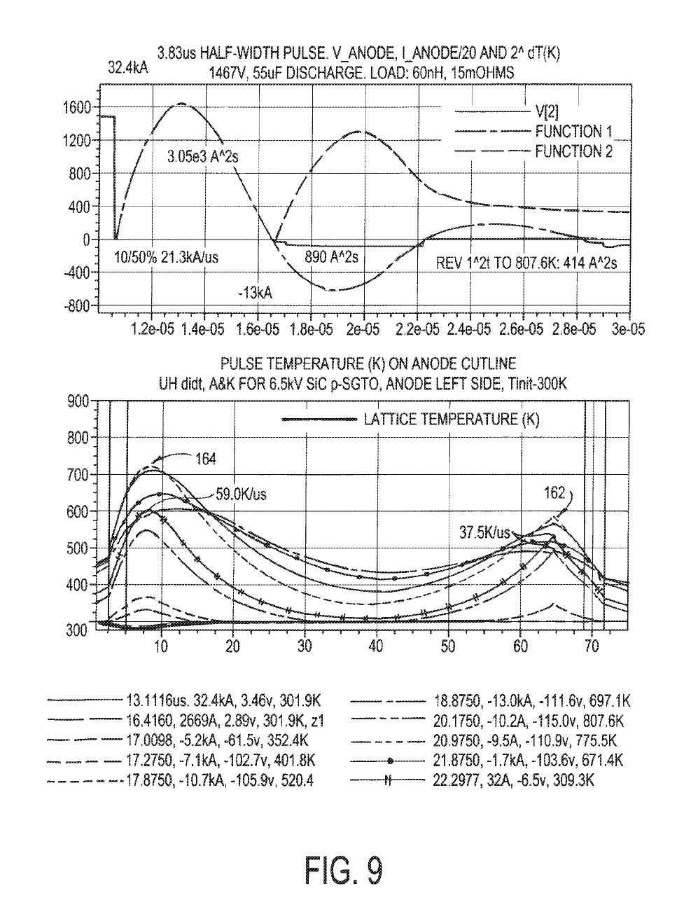

FIG. 9 illustrates voltage, current, and temperature responses for an exemplary device with localized doping spikes at both emitters, having now included the upper emitter (anode here) spike to get the exact profile shown in FIG. 7. The temperature spike on the anode side of the device 164 (the left side of the chart) is reduced as compared to FIG. 8, which did not include a localized doping spike region at emitter 1. In FIG. 9, the peak temperature at emitter 1 is about 700K, which is approximately 150K lower than the exemplary lower emitter only localized spike of the FIG. 8 case. This is not as dramatic an improvement, but the temperature change per μs at the upper emitter has been reduced from 297K per μs to 59K per μs. On the cathode side (the right side of the chart), the peak temperature 162 remained largely unchanged as compared to FIG. 8, but the temperature change per μs decreased from 91.2K per μs to 37.2K per μs. Note that the simulation test circuit parameters are identical for FIGS. 2, 8, and 9. In fact, the same R, L, C values (e.g., 15 mΩ, 60 nH, 55 μF) are used for all of the 3.8 us cases shown in FIGS. 2, 8, and 9, including the silicon case shown in FIG. 4. Similarly all of the sub us cases shown in FIGS. 5, 10, 11 and 12 have the same R, L, C (e.g., 5 mΩ, 4 nH, 15 μF).

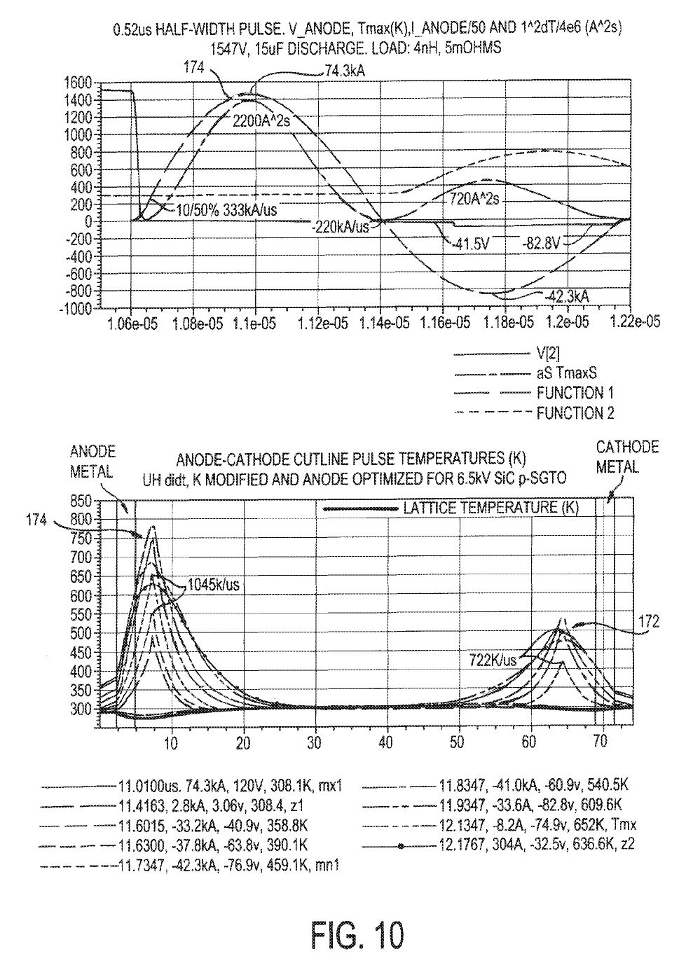

FIG. 10 illustrates voltage, current, and temperature responses for the exemplary device illustrated in FIG. 7 in which the test conditions have been adjusted for a 0.52 μs half-width pulse and a 15 μF, 1547V discharge into a 4 nH, 5 mΩ load circuit. The peak current 170 is approximately 74.3 kA. The anode side junction has a temperature change per second of approximately 1045K per μs, and the cathode side junction has a temperature change of approximately 722K per μs. The peak temperature change at the emitter 1 junction 174 is approximately 585K, and the peak temperature change on the emitter 2 junction 172 is approximately 240K.

Various standard and exemplary cases are summarized in Tables 1, 2A and 2B. In Table 1, all cases are SiC p-type devices, three with a 3.83 us forward current half widths and one with a 0.52 us half width. Tables 2A and 2B allow similar BV silicon and SiC cases to be compared. Specifically, Table 2A is at roughly 3.85 us halfwidth and Table 2B is at roughly 0.55 us half width. Table 2B results strongly favor silicon because silicon starts with as much as an order of a magnitude lower for its avalanche breakdown voltage. To simplify comparison, the column variables are identical across all 3 tables. In column 1 of each row, the Tables provide cross references to the figure from which the raw data was taken as well as notes giving the pulse discharge circuit and initial discharge voltage. Because the figures of merit are ratios they are relatively independent of initial voltage, important to keep in mind in Tables 2A and 2B where the silicon cases were pulsed at a 15% higher voltage, which would put them at a disadvantage. This was not the case because the emitter junction temperature rises at first zero crossing were minimal in all cases, whether silicon or SiC.

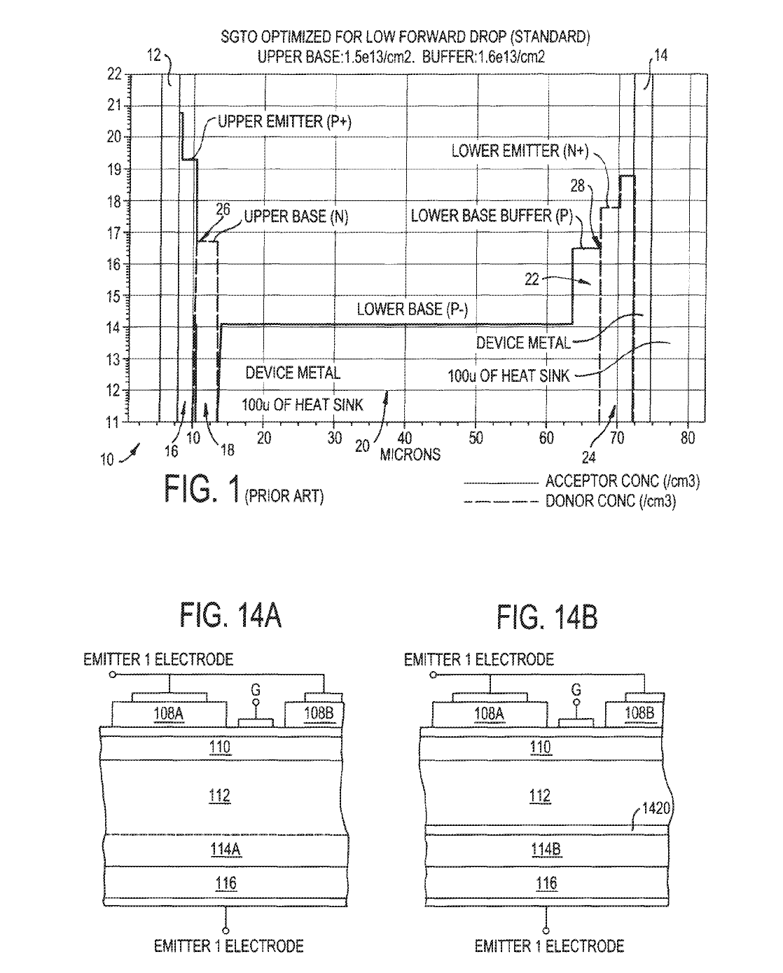

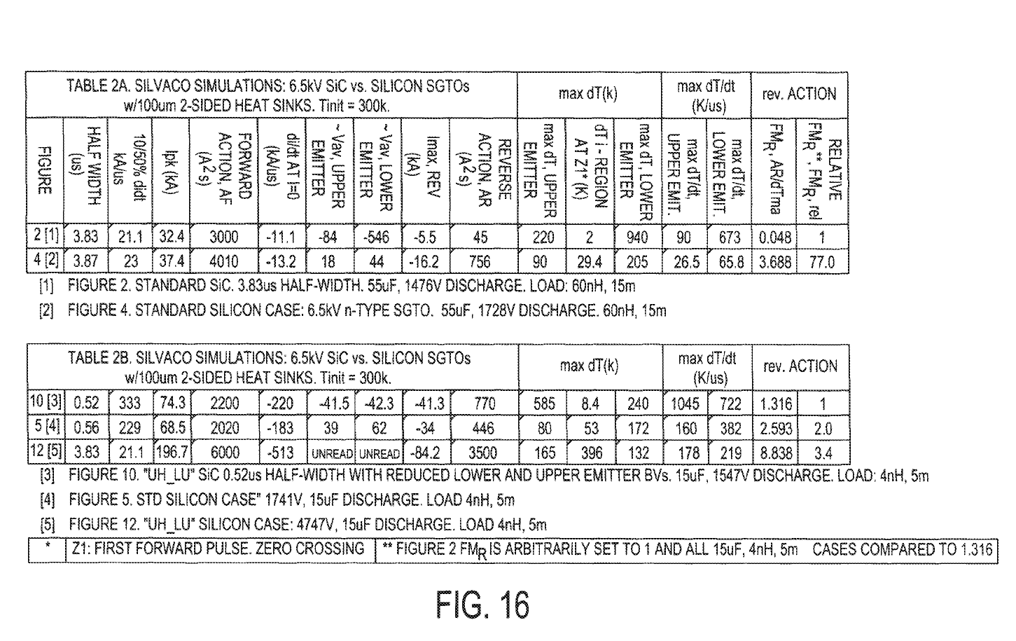

The various parameters identified in the figures given above have been included in Tables 1, 2A, and 2B, which are shown as FIGS. 15 and 16. Tables 1, 2A, and 2B include parameters for di/dt, Ipeak, forward and reverse action “AF” and “AR”, voltages, and approximate maxima of the dT/dt at the emitter 1 and 2 junctions. It is desirable to have a device with high forward action AF and sufficiently high AR to withstand the reverse current imposed by the circuit. Note that column 1 identifies the applicable figure number and a reference to the test circuit and conditions for that row of table entries. Also included in the reference is a case identification—standard, UH represents ultra high action along with a further tag identified which junctions, upper “U” or lower, “L” or both, had been modified for reduced reverse voltage breakdown voltage. Accordingly, a Reverse Action Figure of Merit, FM_{R}, is defined as the reverse action divided by the maximum temperature rise in the device during the reverse current, which will generally be at one or other of the emitter junctions. Similarly FM_{F}, the Forward Action Figure of Merit, is defined as the forward action divided by the maximum temperature rise in the device during the forward current. Typically, the FM's tend to be high, have lots of action but little dT. For example, the first row illustrates the prior art device of FIGS. 1-2 having a reverse action of 45 A² seconds, and a max temperature change of 940K, which occurs at the junction on the lower (emitter 2) side of the device, which for this p-type device is the cathode. The reverse current only reaches −5.5 kA which is why the anode emitter dT is lower than the exemplary case dT's which reach ˜−13 kA. For the standard case, the FM_{R} is calculated to be 0.048 while our exemplary cases are much, much higher, 0.821 for cathode side only and 2.32 for both anode and cathode doping spikes. For comparison sake the Tables define a Relative Reverse Action Figure of Merits, FM_{R},rel, arbitrarily assigning 1.0 to that of the standard device of FIG. 2 in row 1 of Table 1. This comparison is most meaningful for the FIGS. 2, 8, and 9 cases with the same discharge circuit and similar forward current half widths, in this case 3.8 μs. No FM_{R},rel is given for the FIG. 10 in Table 1 whose half width is 0.52 μs. Note that UH indicates an ultra-high design with either or both emitter 1 and emitter 2 having purposely lower avalanche breakdown voltages and L and or U indicating which.

The device in the second row corresponds to a SiC embodiment of the device 100 having a lower localized doping spike region at the emitter 2 junction on the lower side, which is the cathode of this p-type SiC. The Figure of Merit for this embodiment is 17.2 times greater than the prior art device. The third row corresponds to an embodiment of the device 100 illustrated in FIG. 7 and having an upper localized doping spike region 132 at the upper junction 118 and a lower localized doping spike region 136 at the lower junction 120. The figure of merit for this embodiment is 48.1 times greater than the prior art device. The fourth row corresponds to an embodiment of the device 100 having an upper localized doping spike region and a lower localized doping spike region, and that is tested according to the conditions illustrated in FIG. 9. The figure of merit for this embodiment is 27.5 times greater than the prior art device. Note that the forward action for a given test are essentially the same, a proof that we have not materially changed the forward conduction characteristics by introducing properly localized doping spikes, which themselves have higher recombination rates, but because the blocking junctions are narrower, a minimal increase in net recombination in the upper and lower base regions.

Table 1 shown in FIG. 15 demonstrates the various embodiments of the present disclosure significantly improve over the prior art devices without any reduction in forward action capability and without any added thickness to the device itself. The figures of merit can be further increased by increasing localized doping concentrations, by reducing the width of the localized doping spikes, or both, providing the majority of the reverse voltage on the base side of the emitter junction is within the spike region and that the on-state recombination in the spike region during forward conduction has a minimal affect at forward pulse current levels.

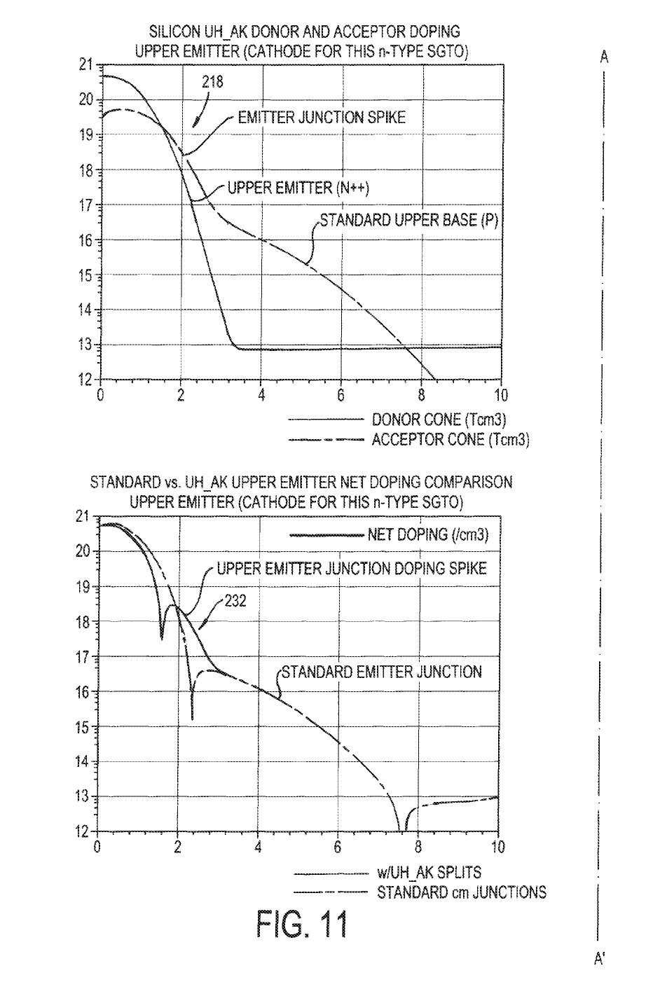

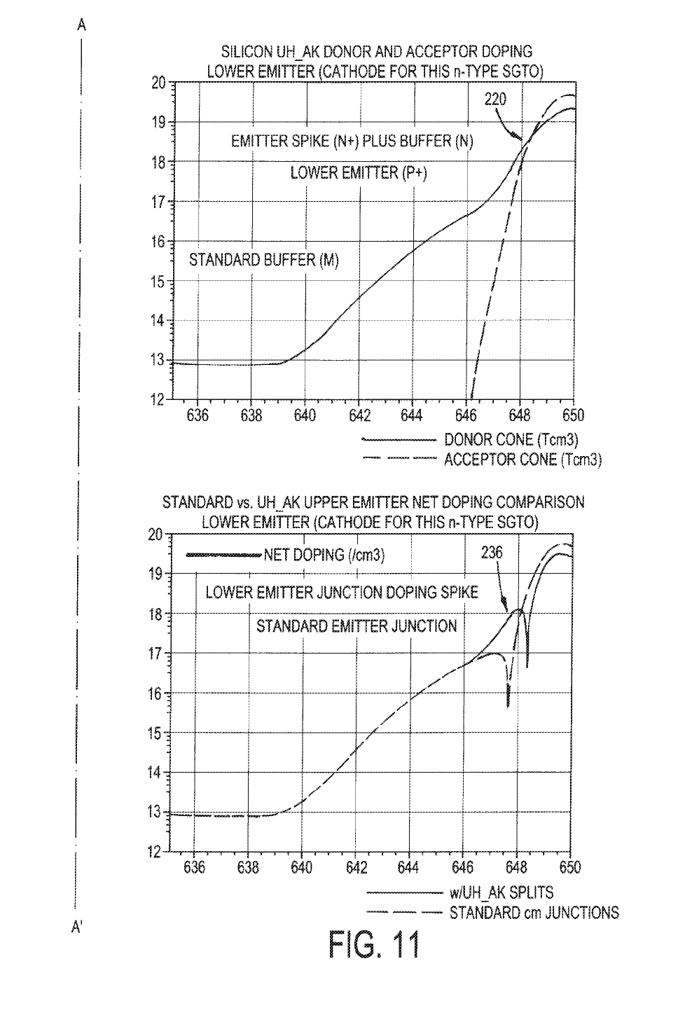

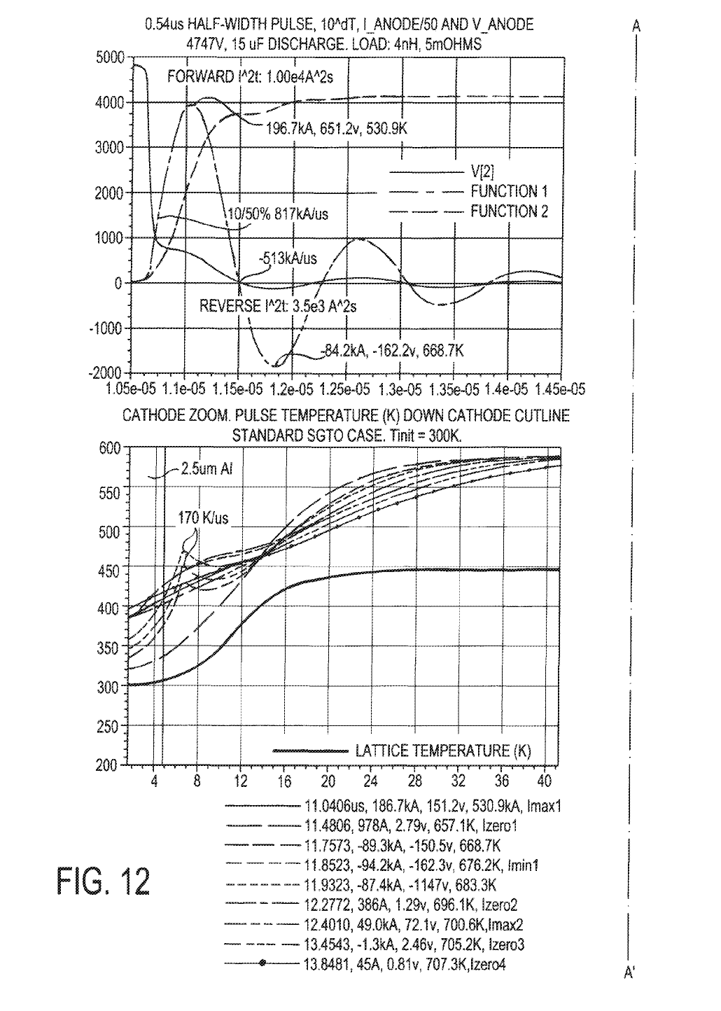

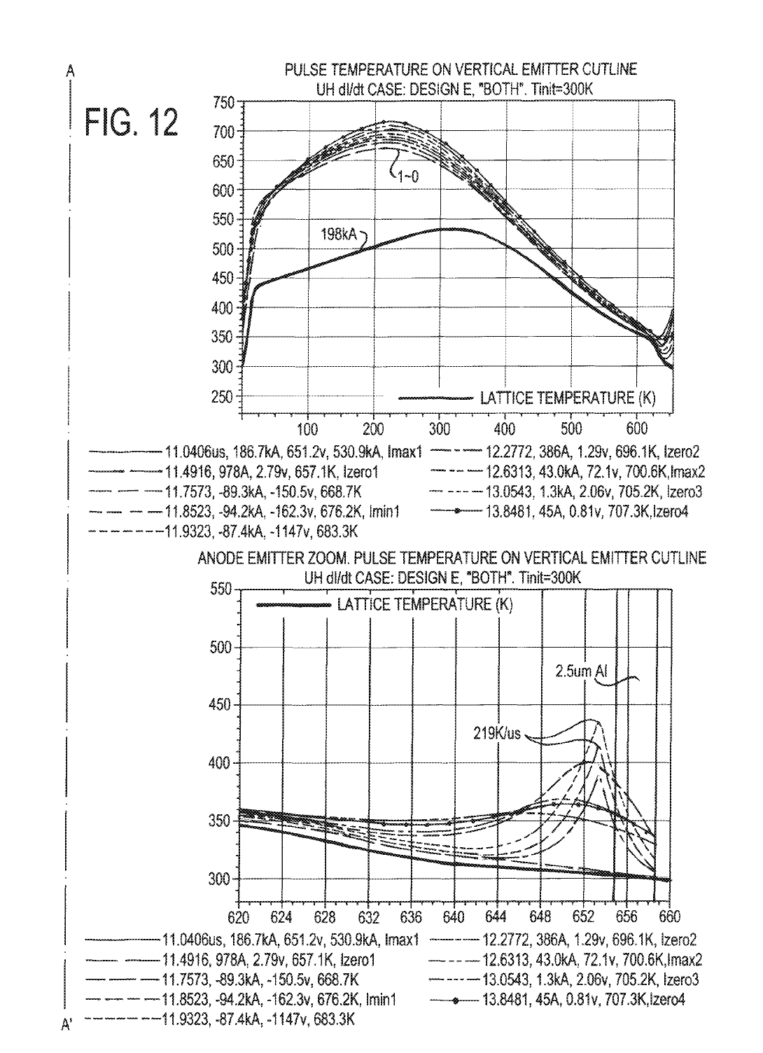

The top two graphs in FIG. 11 illustrate donor and acceptor concentrations near the upper emitter junction 218 and the lower emitter junction 220 of the latching device 200. The bottom two graphs of FIG. 12 compare the doping profile of the latching device 200 to a prior art Si n-type 4-layer latching device such as an SGTO. As can be seen, the upper localized doping spike region 232 and the lower localized doping spike region 236 result in a significantly larger net doping concentration than prior art devices but over such a short distance as to have virtually no impact on forward action.

FIG. 12 illustrates voltage, current, and temperature responses of a 0.54 μs pulse for an exemplary embodiment of latching device 200 having an upper localized doping spike region 232 and a lower localized doping spike region 236. The results of the test are included in Tables 2A and 2B shown in FIG. 16. Rows 1-3 represent prior art devices, and row four represents an exemplary embodiment of the latching device 200.

If the latching device 200 is symmetric blocking, the emitter 1 junction avalanche breakdown voltage can be reduced to lower its reverse current dT. In pulse discharge an anti-parallel diode with as low an Ld as possible can be used. This combination would allow more time to transfer current into the diode without the emitter 2 junction going into avalanche. This combination may increase forward losses but this can be offset by the increased thermal capacity for the now much wider lower base, especially for short pulses in which there is little heat flow out of the device. This increased thermal capacity also applies to the emitter 2—lower base. It will, in many cases make the emitter 1 dT the failure point. This scenario makes a lot of sense but does call for about as two times thicker wafer or lower base epi for the same voltage rating.

As shown in Tables 2A and 2B, rows 3 and 4 are both Silicon n-type SGTOs. Row three corresponds to a prior art device with a narrow pulse width of 0.56 μs and a discharge of a 15 uF capacitor at 1741V. Row four corresponds to an exemplary embodiment of the latching device 200, with a narrow pulse width of 0.54 μs and a discharge of a 15 uF capacitor at 4747V. In the exemplary latching device 200 (and as illustrated in FIG. 13), the latching device 200 heats up more in the main portion of the device rather than the junctions. The result is a very large figure of merit of 46.2, which is a significant improvement over the prior art device in row three.

Table 3, below, consolidates performances of prior art devices and devices of the present disclosure and presents the inherent reverse action capability in terms of reverse action per degree centigrade or Kelvin. The devices of the present disclosure have figures of merit significantly greater than the prior art devices. Due to SiC devices having such a high breakdown voltage at their lower emitter junction the FIG. 2 state of the art device, at 0.048 A²s/K, is essentially limited to critically or overdamped pulses. On the other hand, standard silicon latching devices with their 6 to 10 times poorer avalanche voltage rating would be expected to have a 6² to 10² advantage, which is borne out by the FIG. 4 case with its 1.8 A's/K rating turns out to be 6.1² times that for SiC. Note that both devices had the same RLC and the limiting junction was the lower emitter.

Applying the doping spike to the lower emitter of the SiC device during epi growth reduced the lower emitter junction BV sufficiently to that the device is now limited by the upper emitter junction, and the FIG. 8 case action per degree K has been increased by a factor of 24.4. When we also insert a doping spike at the upper emitter there is a further factor of 3.6 improvement to 4.28 A²s per degree K as seen in the FIG. 9 case and the limiting junction has moved back to the lower emitter.

The FIG. 10 SiC case doping profile is identical to that of the FIG. 9 case but with its much lower RLC has a pulse halfwidth of about 0.5 μs and the lower emitter junction temperature rise has increased despite the decrease in the reverse action. The increase is due to primarily to the fact that the heat gets a much shorter time to spread away from the junction so a lower effective heat capacity. This, coupled with the fact that the device base regions are comparatively very poorly modulated have dropped the action per degree K by a factor of 2.4. Note that the temperature rise is 585 K. On the other hand, the FIG. 10 case of Table 2B shows the forward action of 2200 A²s to the first zero crossing of this case is only 8.4 K and the forward action is 2200 A²s for a forward action rating of 262 A²s per degree K. If our critical dT is 700 C this infers an allowable forward action of 183400 A's. Fortunately, during the forward pulse the emitter junctions are relatively cool but not negligible and we can expect the allowable reverse action to approach 700*1.8=1260 A²s.

TABLE 3
Prior art and exemplary reverse action figures of merit of SIC and
silicon action capability for approximately 3.8 us (RLC = 15 mΩ, 60
nH and 55 ΩF) and approximately 0.5 us RLC = 5 mΩ, 4 nH and 15 μF)

| | | | halfwidth | reverse | dT, max | | Action/ |
|---|---|---|---|---|---|---|---|
| FIG. | Semiconductor | Case | (us) | action (A²s) | (K) | location | deg K |
| 2 | SiC | Standard. 55 uF, 1487 V. | 3.8 | 45 | 940 | L | 0.048 |
| 8 | SiC | L only. 55 uF, 1487 V. | 3.8 | 657.1 | 560 | U | 1.173 |
| 9 | SiC | L and U. 55 uF, 1487 V. | 3.8 | 1841.9 | 430 | L | 4.283 |
| 10 | SiC | L and U. 15 uF, 1547 V. | 0.5 | 1053.0 | 585 | L | 1.800 |
| 4 | Silicon | standard. 55 uF, 1741 V | 3.8 | 369.0 | 205 | L | 1.800 |
| 5 | Silicon | standard. 15 uF, 1741 V. | 0.5 | 254.9 | 172 | L | 1.482 |
| 12 [A] | Silicon | L and U. 15 uF, 4747 V | 0.5 | 2121.0 | 165 | L | 12.855 |
| 12 [B] | Silicon | L and U. 15 uF, 4747 V | 0.5 | 2121.0 | 396 | C | 5.356 |

[A], [B]: dT in center of device was primarily generated by the forward action.
Use [A] for comparison.

Turning to FIG. 13, a ThinPak circuit 300 is illustrated and comprises a latching device 100, 200 and at least one antiparallel diode in 302A and the same number of antiparallel diodes in 302B. These are located in such a way to minimize the stray inductance between the latching device and antiparallel diodes as is well known in the art. When the latching device is a formed of a slower turn-on semiconductor, such as Silicon, an antiparallel diode may be formed of a faster turn-on semiconductor, such as SiC. In such a combination, the reverse current seen by the latching device be reduced by the rapid transfer of current into the antiparallel diodes 302A and 302B.

The low L_{D} configuration of FIG. 13 provides another embodiment of a latching device with symmetric blocking. The latching device has only emitter 1 employing the doping spike to reduce its avalanche breakdown voltage and reverse action dT. This combination with a thicker lower base significantly increases forward losses resulting in reducing AF. However, it also increases the lower emitter-base depletion width during the reverse current resulting in orders of magnitude increased thermal capacity. It will, in many cases make the emitter 1 dT the failure point.

As an example, FIG. 13 calls for about a two times thicker wafer or lower base epi for the same voltage rating. The result, for the same voltage rating compared with the asymmetric cases presented above is a much lower AF and an AR limited by the emittter1 dT. In this case, the latching device is only partially symmetric with the BV of the lower emitter junction 120, hereafter BV_{R}, being less than the device rated forward blocking voltage, hereafter BV_{F}. Compared to FIG. 6A, a fully symmetric device would eliminate the buffer region 114 and lower localized doping spike region 136 and the lower base region 112 would be at least twice as thick as well as half the doping level. In a partially symmetric device, the lower localized doping spike region 136 would be omitted and buffer region doping and thickness adjusted such that the resultant depletion extending upward from the lower emitter junction 120 supports the desired partial voltage with a modest additional width to prevent forward blocking depletion region punch-through to emitter 2. Having the lower emitter junction 120 supported the desired partial voltage can be implemented using epitaxy or any other operations that are well known to designers of latching devices.

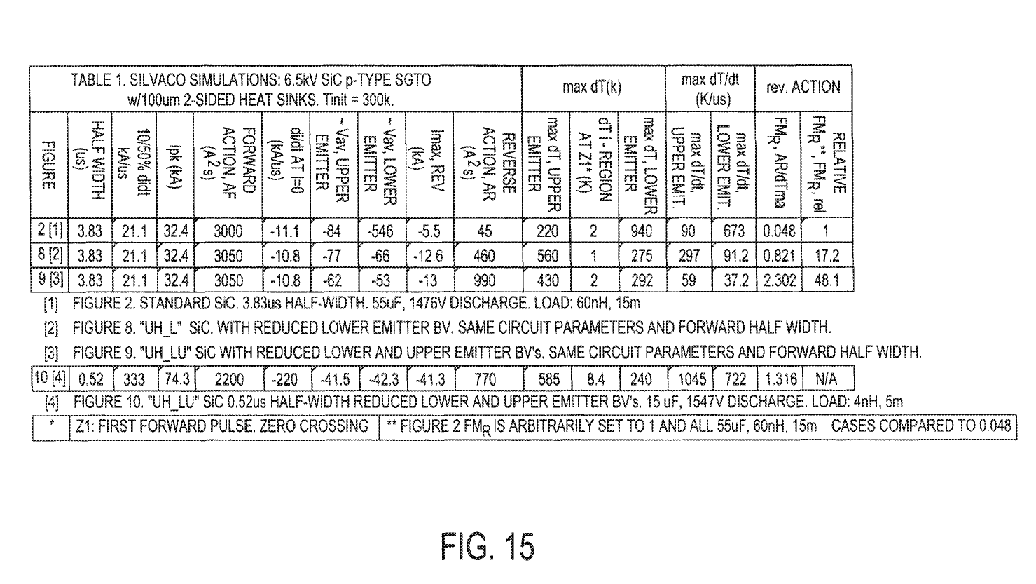

FIG. 14A is an embodiment of a partially symmetric device 1400 with a 6.5 kV BV_{F} silicon device. Lower base region 112: 500 um doped at 1e13/cm³. Buffer region 114A: net integrated doping sufficient to prevent forward bias punch-through at rated BV_{F}, 2e12/cm², for example. With a constant doping of 5e14/cm³ and thickness 40 μm a quick BV simulation predicts a BV_{R} of about 400 volts with a 30 μm depletion region extending up from lower emitter junction 120. In reverse avalanche the losses are high, but the related heat capacity is increased over an order of magnitude. With the various exact simulation tools available the above is quickly optimized. Given that the buffer region 114 was likely 20 μm the base thickness has only increase by 20 μm, or 2% of the emitter 1 to emitter 2 thickness, and thus minimal AF reduction. Also, because the order of magnitude increase in the thermal capacity is now at 30 μm rather about 1.5 μm, the emitter 2 AR will increase if L_{D} is small and diode modulation levels increase sufficiently quickly to shift the reverse action into the diode before emitter 2 dT becomes dominant. Obviously, the wider the pulse, the larger share of reverse action diverted from the latching device. The partially symmetric approach largely avoids the difficulties related to the properties of thicker device, both in the cost and in the qualities of that material (e.g., whether silicon or SiC).

Another embodiment is shown in FIG. 14B for a partially symmetric device 1400. Here doping layer 1420 is introduced with the requisite integrated doping to prevent punch-through at BV_{F}. The doping layer's 1420 thickness can be much wider than the doping spike. This is fortunate in devices where there may be considerable thermal budget required to form the upper emitter and base. Keeping BV_{F} and overall emitter 1 to emitter 2 distance the same we come up with the following for the FIG. 14B example. Lower base region 112 thicker by about 5 μm to support the approximately 75 volts that were supported by buffer region 114A in FIG. 14A. A generous blocking layer 1420 of 10 μm, leaving 25 μm for buffer region 114B, which now can be as lightly doped as we can manage. However, because it is so thin it will support nearly the same voltage whether doped at 1e14/cm³ at 2e13/cm³, about 500V, roughly 20V/μm. Thus, one would expect a 1 kV BV_{R} with a 50 μm buffer region 114B and expect an insignificant reduction in forward action capability.

FIG. 13 represents a ThinPak lid, which provides an ideal platform mechanically and in terms of parasitic inductance and capacitance. The gate drive typically requires no local energy storage and utilizes a high current high di/dt current drive into the upper gate electrode such that the gate current amplitude reaches many times the turn-on threshold in the order of 50 to 100 ns. Once triggered on the gate current is negligible so no intentional damping resistor is advise, threshold current is set by a pure resistor shorting the gate and upper emitter that is preferably mounted on the oversized ThinPak lid sized to keep the upper gate-emitter forward bias less than the turn-on voltage threshold in the presence of dv/dt, thermal and photo-generation. Whatever current level this amounts to, it is simple enough to generate 10 to 100 times that current. Note, too, that the device needs no turn-off gate drive, just time for the amplitude of the pulse oscillations to decay sufficiently for the gate shorting resistor to take care of it.

Methods for manufacturing four-layer latching devices are generally known in the art. The latching devices of the present disclosure are manufactured according to similar method but with the added introduction of localized doping spikes during the manufacturing process. The localized doping spikes may be introduced with an implant and diffusion or by epitaxy, depending on the semiconductor material being used and the desired doping profile. By doing so, the four-layer latching device has a relatively lower emitter-base break down voltage. For example, a SiC device with the modified emitter depletion regions could have a reduction in avalanche break down voltage of about a factor of 10 for an estimated increase in reverse action rating of about a factor of 3.

The latching devices of the present disclosure are described above as being formed of Si or SiC. However, the advantages of the present disclosure may be realized in other semiconductor materials as well. These and other advantages of the present disclosure will be apparent to those skilled in the art from the foregoing specification. Accordingly, it is to be recognized by those skilled in the art that changes or modifications may be made to the above-described embodiments without departing from the broad inventive concepts of the invention. It is to be understood that this invention is not limited to the particular embodiments described herein, but is intended to include all changes and modifications that are within the scope and spirit of the invention.

1. A semiconductor latching device, comprising:
an upper emitter junction formed at an interface between an upper emitter region having a first doping concentration and an upper base region having a second doping concentration; and
a lower emitter junction formed at an interface between a lower base region having a third doping concentration and a lower emitter region having a fourth doping concentration;
an upper localized doping spike region at the upper emitter junction, wherein the upper localized doping spike region has an upper localized doping concentration greater than the second doping concentration.

2. The device of claim 1, wherein the lower base region further comprises a buffer region at the lower emitter junction, the buffer region having a fifth doping concentration, and wherein the buffer region comprises a lower localized doping spike region at the lower emitter junction, wherein the lower localized doping spike region has a lower localized doping concentration greater than the fifth doping concentration.

3. The device according to claim 1, wherein:
the upper localized doping concentration is at least 50% greater than the lower doping concentration.

4. The device according to claim 1, wherein:
the upper localized doping concentration is at least two times greater than the lower doping concentration.

5. The device according to claim 1, wherein:
the upper localized doping concentration is at least three times greater than the lower doping concentration.

6. The device according to claim 2, wherein:
the lower localized doping concentration is at least 50% greater than the fifth doping concentration.

7. The device according to claim 2, wherein:
the lower localized doping concentration is at least two times greater than the fifth doping concentration.

8. The device according to claim 2, wherein:
the lower localized doping concentration is at least three times greater than the fifth doping concentration.

9. The device of claim 1, wherein:
the upper emitter region includes at least a p-type silicon carbide material;
the upper base region includes at least an n-type silicon carbide material;
the lower base region includes at least a p-type carbide silicon material;
the lower emitter region includes at least an n-type silicon carbide material.

10. The device of claim 1, wherein:
the upper emitter region includes at least a n-type silicon material;
the upper base region includes at least an p-type silicon material;
the lower base region includes at least a n-type silicon material;
the lower emitter region includes at least an p-type silicon material.

11. A semiconductor latching device, comprising:
an upper emitter junction formed at an interface between an upper emitter region having a first doping level and an upper base region having a second doping level; and
a lower emitter junction formed at an interface between a lower base region having a third doping level and a lower emitter region having a fourth doping level;
wherein the lower base region further comprises a buffer region at the lower emitter junction, the buffer region having a fifth doping concentration, and further wherein an upper localized doping spike region is in the buffer region and has an upper localized doping concentration is greater than the fifth doping concentration.

12. The device of claim 11, wherein the upper base region further comprises a lower localized doping spike region at the upper emitter junction, wherein the lower localized doping spike region has a lower localized doping concentration greater than the lower doping concentration.

13. The device of claim 11, wherein the upper localized doping concentration is at least 50% greater than the fifth doping concentration.

14. The device of claim 11, wherein the upper localized doping concentration is at least two times greater than the fifth doping concentration.

15. The device of claim 11, wherein the upper localized doping concentration is at least three times greater than the fifth doping concentration.

16. The device of claim 11, wherein the lower localized doping concentration is at least 50% greater than the lower doping concentration.

17. The device of claim 11, wherein the lower localized doping concentration is at least two times greater than the lower doping concentration.

18. The device of claim 12, wherein the lower localized doping concentration is at least three times greater than the lower doping concentration.

19. The device of claim 11, wherein:
the upper emitter region includes at least a p-type silicon carbide material;
the upper base region includes at least an n-type silicon carbide material;
the lower base region includes at least a p-type carbide silicon material;
the lower base region includes at least an n-type silicon carbide material.

20. The device of claim 11, wherein:
the upper emitter region includes at least a n-type silicon material;
the upper base region includes at least an p-type silicon material;
the lower base region includes at least a n-type silicon material;
the lower base region includes at least an p-type silicon material.

21. A semiconductor latching device, comprising:
an upper emitter junction formed at an interface between an upper emitter region having a first doping concentration and an upper base region having a second doping concentration; and
a lower emitter junction formed at an interface between a lower base region having a third doping concentration and the lower emitter region having a fourth doping concentration;
wherein the upper base region comprises an upper localized doping spike region at the upper emitter junction, wherein the upper localized doping spike region has an upper localized doping concentration greater than the second doping concentration, and
wherein the lower base region does not include a lower localized doping spike region at the upper emitter junction and a buffer region at the lower emitter junction.

22. A semiconductor latching device, comprising:
an upper emitter junction formed at an interface between an upper emitter region having a first doping concentration and an upper base region having a second doping concentration; and
a lower emitter junction formed at an interface between a lower base region having a third doping concentration and the lower emitter region having a fourth doping concentration;
wherein the upper base region comprises an upper localized doping spike region at the upper emitter junction, wherein the upper localized doping spike region has an upper localized doping concentration greater than the second doping concentration, and
wherein the lower base region does not include a lower localized doping spike region at the upper emitter junction,
wherein the lower base region comprises a buffer region having a fifth doping concentration at the lower emitter junction.

23. The device of claim 22, further comprising a doping blocking layer positioned formed at an interface between the lower base region and the buffer region.
